(19) United States
(12) Patent Application Publication
(10) Pub. No.: US 2007/0154849 A1
(43) Pub. Date: Jul. 5, 2007

(54) Method of fabricating a semiconductor transistor

(75) Inventors: Jin Youp Kim, Seoul (KR); Jeong Yei Jang, Suwon-si (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Dongbu Electronics Co., Ltd.

(21) Appl. No.: 11/646,436

(22) Filed: Dec. 28, 2006

(30) Foreign Application Priority Data
Dec. 30, 2005 (KR) 10-2005-0134879

(51) Int. Cl. G03F 7/26

(52) U.S. Cl. 430/316; 430/313

(57) ABSTRACT

A method for fabricating a semiconductor transistor having a size of 90 n m or less includes, sequentially depositing a gate oxide film, a poly silicon, an organic antireflection film, and a photo-resist on a substrate; exposing and developing the photo-resist to form a photo-resist pattern having a critical dimension DICD; etching the antireflection film using the photo-resist as a mask to form an antireflection film pattern; etching the poly silicon using the photo-resist as a mask to form a first poly silicon pattern and a second poly silicon pattern on a portion of the gate oxide film; and removing the second poly silicon pattern and the portion of the gate oxide film.

This application is based upon and claims the benefit of priority to Korean Application No. 10-2005-0134879, filed on Dec. 30, 2005, the entire contents of which are incorporated herein by reference.

### BACKGROUND

1. Technical Field

The present invention relates to semiconductor fabrication technology, and more particularly, to a fabrication method capable of producing small gates in large quantities and manufacturing small gates with reliability.

2. Description of the Related Art

In a semiconductor fabrication process, manufacturing a transistor may affect the proper function of the semiconductor device. Therefore, specific and stable photolithographic and fabrication technologies are needed. As the semiconductor device becomes highly integrated, the design rule of the transistor becomes strict. In order to manufacture a transistor having a size of 90 nm or less based on the design rule of ASIC, an ArF light source should be used instead of a KrF light source, which is currently used in photolithography processes.

However, a photolithography process using the ArF light source has some problems which are discussed below.

First, an adhesive strength between a polymer and a photo-resist of the ArF light source having a wavelength of 193 nm. Thus, a tolerance to plasma is reduced and deformation easily occurs in an etching process so as to generate inferior device characteristics.

Second, the photo-resist of the ArF light source reacts to etching radicals well, thus reducing a margin of the etching process.

Third, an aspect ratio of the photo-resist according to decreasing pitch size increases and the photo-resist may bend or break down.

Fourth, a Critical Dimension(CD) is changed by Critical Dimension Uniformity of CD in a wafer, a line edge roughness(LER), and a number of measurements at ArF photo-resist in CD SEM using high energy (voltage 800 to 1500 KeV).

### BRIEF SUMMARY

Consistent with the present invention there is provided a method of fabricating a semiconductor transistor that substantially obviates one or more problems due to limitations and disadvantages of the related art.

Consistent with the present invention there is provided a semiconductor transistor satisfying the strict design rule by complementing a weak point of a conventional technology.

Consistent with the invention, as embodied and broadly described herein, there is provided a method of fabricating a semiconductor transistor of which size is 90 nm or less comprising: sequentially depositing a gate oxide film, a poly silicon, an organic antireflection film, and a photo-resist on a substrate; exposing and developing the photo-resist to form a photo-resist pattern having a critical dimension DICD; etching the antireflection film using the photo-resist as a mask to form an antireflection film pattern; etching the poly silicon using the photo-resist as a mask to form a first poly silicon pattern and a second poly silicon pattern on a portion of the gate oxide film; and removing the second poly silicon pattern and the portion of the gate oxide film. In etching the antireflection film using the photo-resist as the mask, the photo-resist pattern is etched laterally to form a second photo-resist pattern having FICD smaller than DICD as critical dimension, and is performed under low gas ratio of Cl₂/O₂, low pressure, and low bias power.

It is to be understood that both the foregoing general description and the following detailed description consistent with the present invention are exemplary and explanatory and are intended to provide further explanation consistent with the invention as claimed.

### BRIEF DESCRIPTION OF THE DRAWINGS

The accompanying drawings, which are included to provide a further understanding consistent with the invention and are incorporated in and constitute a part of this application, illustrate embodiment(s) consistent with the invention and together with the description serve to explain the principle consistent with the invention. In the drawings:

FIGS. 1a through 1f are cross-sectional views for describing a fabrication process of a semiconductor transistor consistent with the present invention.

FIG. 2 shows a gate structure of a transistor manufactured consistent with the present invention.

FIGS. 3 is a cross-sectional view of an element of a sample transistor for evaluating the transistor manufactured by a method consistent with the present invention.

FIG. 4 shows an experiment result by a factor, which can control output of C-Cl based polymer generated in etching an antireflection film.

FIG. 5 shows the verification result by main factors for minimizing variation of critical dimension if a poly silicon gate is closely arrayed or not.

FIG. 6 is a graph analyzed by 6-sigma regression by measuring variation of FICD according to the variation of DICD.

FIG. 7 is a box plot comparing an LER in a region where lines are sparse with conventional LER at 31 semiconductor chips after an etching process.

FIG. 8 shows thickness of the PR remained after an etching process is measured by using a cross session SEM.

FIG. 9 is box plot showing an amount of the remainder of poly silicon according to the etching time.

FIG. 10 is a SEM photo of a semiconductor transistor manufactured consistent with the present invention.

FIG. 11 is a TEM photo of a semiconductor transistor manufactured consistent with the present invention.

FIG. 12 shows a graph of Ioff variation according to Idr variation for evaluating linearity of NMOS transistor consistent with the present invention.

### DETAILED DESCRIPTION

Reference will now be made in detail to the preferred embodiments consistent with the present invention, examples of which are illustrated in the accompanying drawings. Wherever possible, the same reference numbers will be used throughout the drawings to refer to same or similar parts.

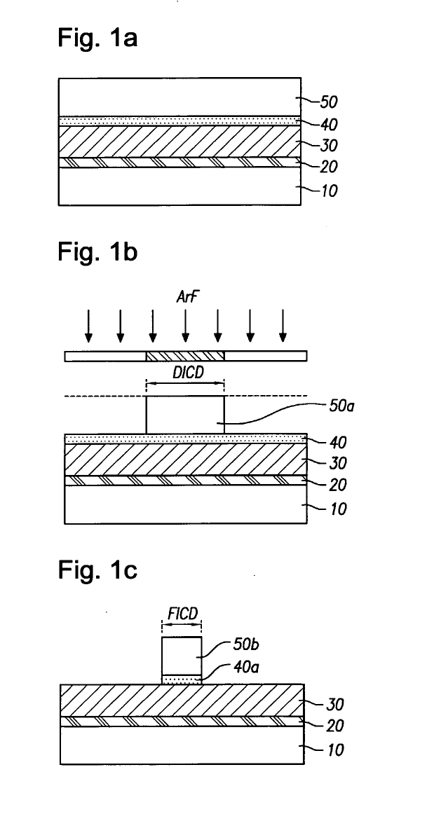

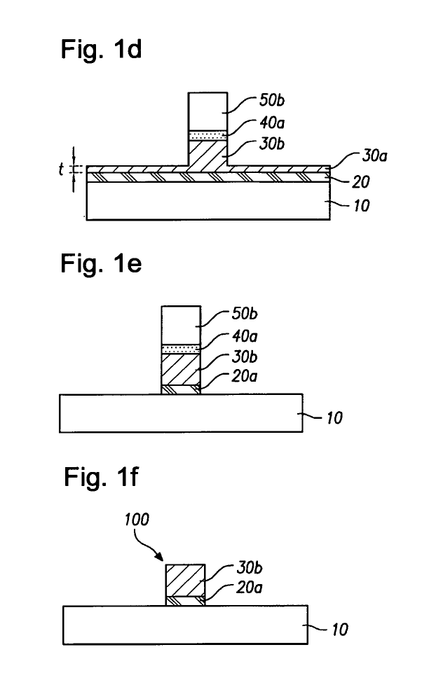

FIGS. 1a through 1f are cross-sectional views for describing a fabrication process of a semiconductor transistor consistent with the present invention.

With reference to FIG. 1a, an oxide film 20, a gate conductor 30, an antireflection film 40, and a photo-resist 50 are sequentially formed on a semiconductor substrate 10.

Consistent with the present invention, antireflection film 40 may be made of an organic film.

As shown in FIG. 1b, photo-resist 50 is exposed and developed after arraying a photo-mask on a substrate 10 so as to form a photo-resist pattern 50a with develop inspection critical dimension (DICD). DICD corresponds to the critical dimension after developing the photo-resist.

With reference to FIG. 1c, antireflection film 40 is selectively etched using photo-resist pattern 50a with the critical dimension, DICD, as a mask to form an antireflection film pattern 40a. In this process, a second photo-resist pattern 50b, of which the critical dimension is reduced to final inspection critical dimension (FICD), is obtained by laterally etching photo-resist pattern 50a. The CD of photo-resist pattern is reduced by applying a trim technology. Therefore, a CD bias is about 20 nm to 40 nm and a margin between the LER of the photo-resist pattern and the depth of focus(DOF) is secured. A transistor having a size of 90 nm or less may be manufactured consistent with the above-mentioned processes.

By the trim technology, the amount of the lateral etching of the photo-resist pattern is increased so as to control a top CD of a gate conductor in etching the poly silicon. In this case, a large CD variation is secured, but the margin of the etching process and a thickness of a photo-resist is reduced. Because when the DICD is 100 nm or less the photo-resist pattern is removed by lateral etching before etching the poly silicon, and installing the proper fabrication conditions becomes important.

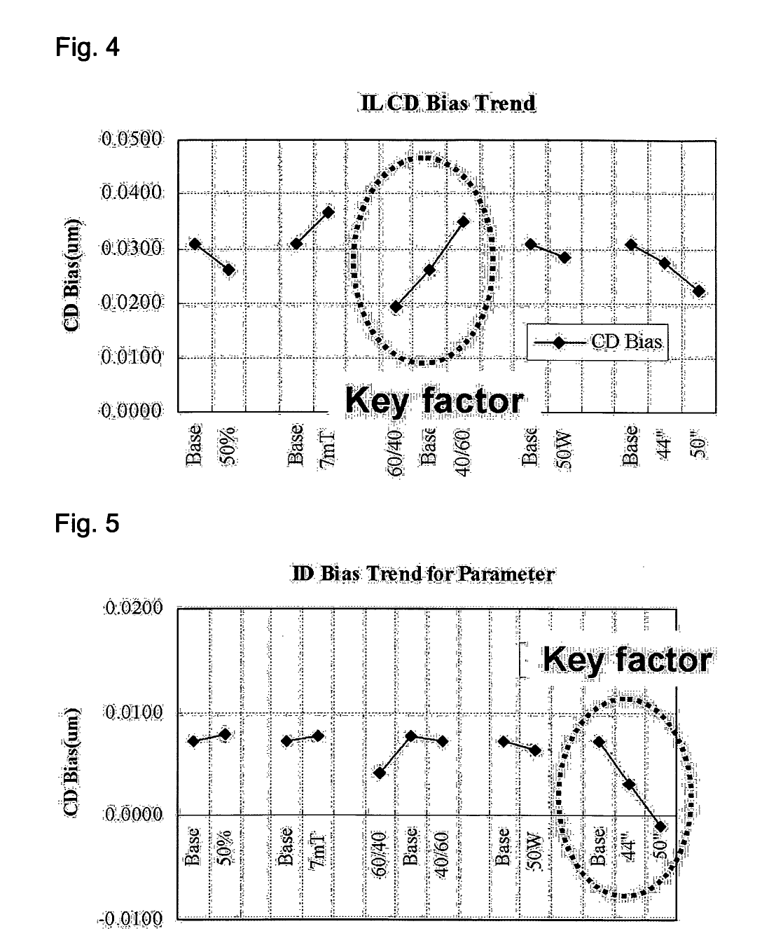

Antireflection film 40 may be formed in-situ in conditions of low pressure, a low ratio of Cl₂/O₂, and a low bias power. The conditions for the fabrication are obtained by the following processes. As shown in FIG. 4, a main factor is the ratio of C1₂/O₂, which may control the CD variation in etching of antireflection film 40. FIG. 4 shows an evaluation result using a window test. In an experiment for the evaluation, a factor capable of controlling the amount of C-Cl based polymer product that is generated in etching antireflection film 40 is selected. The baseline of the antireflection film uses an end point detection (EPD) method for detecting a wavelength of 278.5 nm, and includes a pressure of 10 mT and a source power of 350 W. The ratio of a gas forming reaction radical in a bias power condition of 40 W is used for end point detection (EPD) of detecting wavelength of Cl₂/O₂=50/50.

As shown in the evaluation result of FIG. 4, the reason why the main factor is the gas ratio of Cl₂/O₂ for controlling the CD variation is that a photo-resist of organic material and C-Cl based on the polymer which formed by the antireflection film and the Cl radical react to O₂ according to an increasing amount of O₂, and an amount of free chlorine is increased so that the amount of passive polymers in the lateral side of the photo-resist enlarges the CD variation. Also, when the combination of the gas ratio Cl₂/O₂ is used, the CD is controlled between 20 nm and 35 nm without changing any other process factors.

As shown in FIG. 5, the main factor for minimizing the CD variations if the gate is arranged densely or otherwise depends on a processing time in etching the poly silicon relative to variables in etching the antireflection film.

From the result, it is shown that within 5 nm, little CD variation of the antireflection film exists but, it is confirmed that micro loading is generated by pattern density in the etching step of the poly silicon.

With reference to FIG. 1d again, after etching antireflection film 40 under the process conditions, a first poly silicon pattern 30a remaining under antireflection film pattern 40a and a second poly silicon pattern 30b remaining on a gate oxide film 20 are formed by etching the poly silicon using second photo-resist pattern 50b as a mask. Consistent with the present invention, when etching the poly silicon, the poly silicon with a thin thickness remains on a surface of the substrate without removing all the poly silicon at once. The thickness of second poly silicon pattern 30b remaining on the substrate is on the order of hundreds of angstrom(Å). The reason why second poly silicon pattern 30b remains is because it prevents the silicon substrate under gate oxide film 20 from etching due to low etching select ratio of the poly silicon and gate oxide film in etching the poly silicon.

With reference to FIG. 1e, second poly silicon pattern 30b is completely removed and gate oxide film pattern 20a is formed by removing the gate oxide film located on the outside of the gate region.

With reference in FIG. 1f, the photo-resist pattern and the antireflection film pattern are removed to form gate multi-layer structure 100 comprised of gate oxide film pattern 20a and poly silicon pattern 30b.

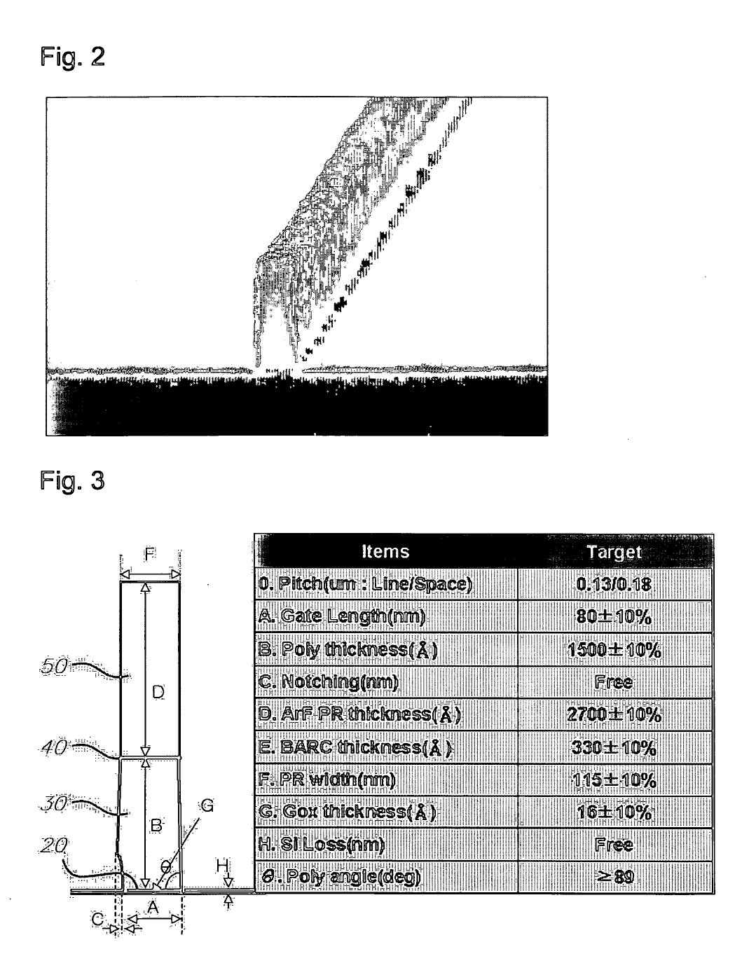

In order to estimate results consistent with the method of fabricating the semiconductor consistent with the present invention, gate multi-layer structure 100 is manufactured to have the same structure and dimensions as shown in FIG. 3, and the result is shown in FIG. 2.

After depositing gate oxide film 20 to have thickness of about 16A , a plasma nitride process is performed, and the photo-resist pattern is formed by using for example, the NSR S306C 193 nm scanner manufactured by Nikon company. Photo-resist material may be SAIL-X108 manufactured ShinEtsu company and anti-reflection film may be AR26-300 organic BARC material manufactured by Shippley company. Also, 6% halftone of attPSM(Phase Shift mask) is used as the photo mask for exposing. The photo-resist is deposited to have a thickness of about 2700 angstrom (Å) in a TEL clean track. The thickness is set with a DOF margin under the minimum margin without loss of the poly silicon. After etching the poly silicon, the thickness of the remaining photo-resist is about 1000 angstrom(Å) To improve the LER of the photo-resist and the margin of the DOF, an organic film is used as the antireflection film instead of an inorganic BARC material, SiON film. The antireflection film is deposited to have thickness of about 330 angstrom(Å).

The etching process, may be performed by using an apparatus which forms radicals by using an inductively coupled plasma process.

As shown in FIG. 2, gate multi-layer having a normal profile is formed without PR residue or under-cut.

FIG. 3 shows basic information about the type of film, size of the pitch, and an aim of fabrication for the transistor consistent with the present invention. Herein the pitch is a pattern having a size of about 0.310 μm as a line/space is 0.130/0.180 μm, and the PR pattern is formed by the ArF PR and the BARC material, and the poly silicon has a thickness of about 1500 angstroms, and the gate oxide film has a thickness of about 16 angstrom. To control the CD variation by using the trim technology in the etching process, the organic BARC material is used instead of the inorganic material, SiON.

The PR and CD of the poly silicon line is measured by a CDSEM of Hitachi company, and a measuring box for LER has a size of 1 μm length and 1.5 μm width and an AMAT Verity CDSEM is used as the measuring box. A cross session SEM is used for observing the transistor profile. The CD and ID variation control, an LER of the transistor line, a PR resistor of the plasma, and the profile of the poly silicon, etc. that may be generated when the Arf Pr is used are measured by using the CDSEM and the cross session SEM. The characteristic of the transistor is estimated by the CD variation control, CD linearity, the LER, the ArF PR and margin, and the result of the PCM, etc. using a Physical control monitor (PCM).

Control of CD Variation

The CD variation control is similar to the explanation above.

Linearity of CD

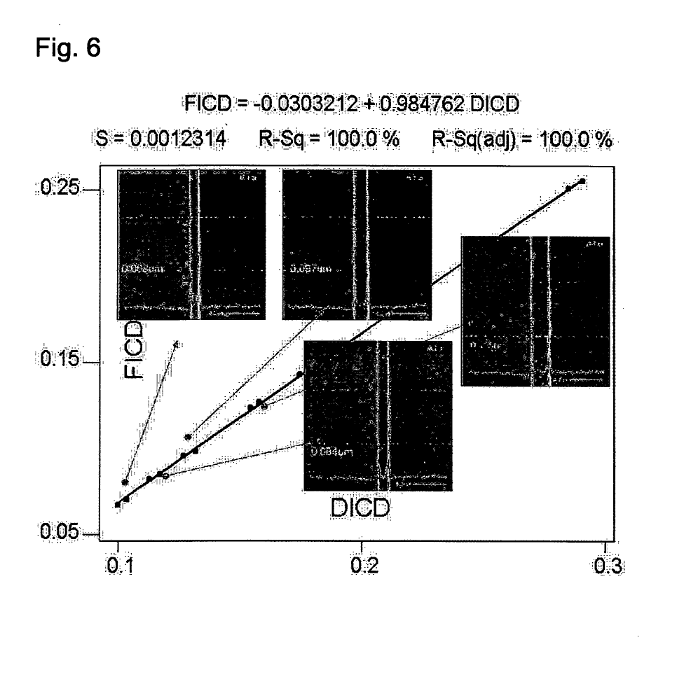

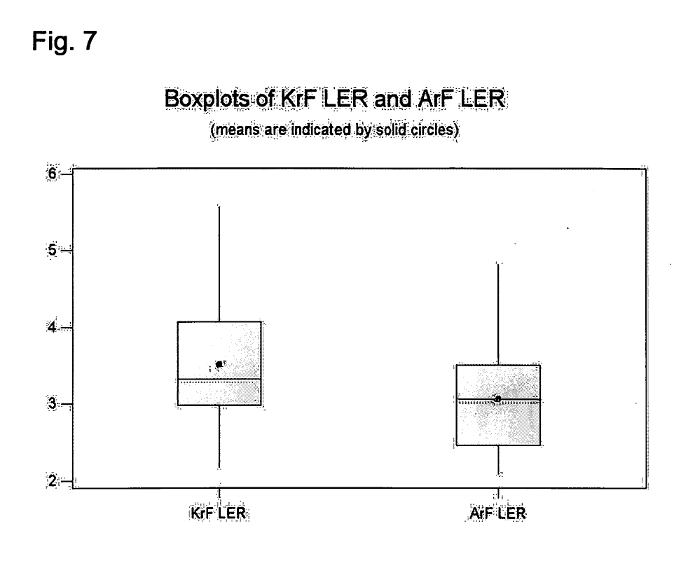

When the DICD is changed from 0.100 μm to 0.300 μm, the variation of FICD is measured to analyze it by regression of 6 sigma and whether mutual dependence exits or not for CD linearity is performed, as shown in FIG. 6.

As shown in FIG. 6, FICD relative to the DICD has a relation expression, 0.98*DICD-0.03 μm, and the relation expression has a significance because a P-value is 0.000 in R-sq =100% and 95% CI. As shown in the SEM photo, lines of the poly silicon normally form the pattern until 70 nm of the transistor. As the linearity of the transistor is confirmed, the FI CD can extend to 70 nm based on the transistor.

LER

LER is an importantly rising problem as a size of the transistor pattern is gradually reduced. When a PR profile is a standing wave by wavelength of light source or is short of margin of focus, sediment such as a PR residue is generated. The residue may increase the LER of the transistor lines, changing characteristics of the transistor, such as Vt and Idr. To solve the problem, a method of rationalizing PR material and temperature of post exposure bake(PEB) is used.

In the estimation, an LER in a region where lines are sparse at 31 semiconductor chips within a wafer after processing, etching is measured by an LER measuring algorithm of a CDSEM of an AMAT company and is compared with the conventional LER that KrF PR is used.

As shown in box plot of FIG. 7, result of a contrast between KrF PR and ArF PR is excellent in aspect of an average (about 3 nm) and the variation, and the result analyzed by 6-sigma(Two-sample T analysis) shows that p-value is 0.031 to pay attention to mutually. The result may be obtained that the LER of ArF PR is satisfactory relative to the KrF.

ArF PR and Margin

Another problem generated by using the ArF PR is that reactivity of a reactive radical in the plasma in processing etching is high relatively to the KrF PR and consumption of the PR is increased so as not to perform properly as a mask in etching poly silicon. To solve the problem, in a BARC etching step in which the PR consumption is generated the most, after confirming when the antireflection film has been completely removed by using EPD, the target over etched gets to be changed from 100% to 30% to rationalize the processing conditions.

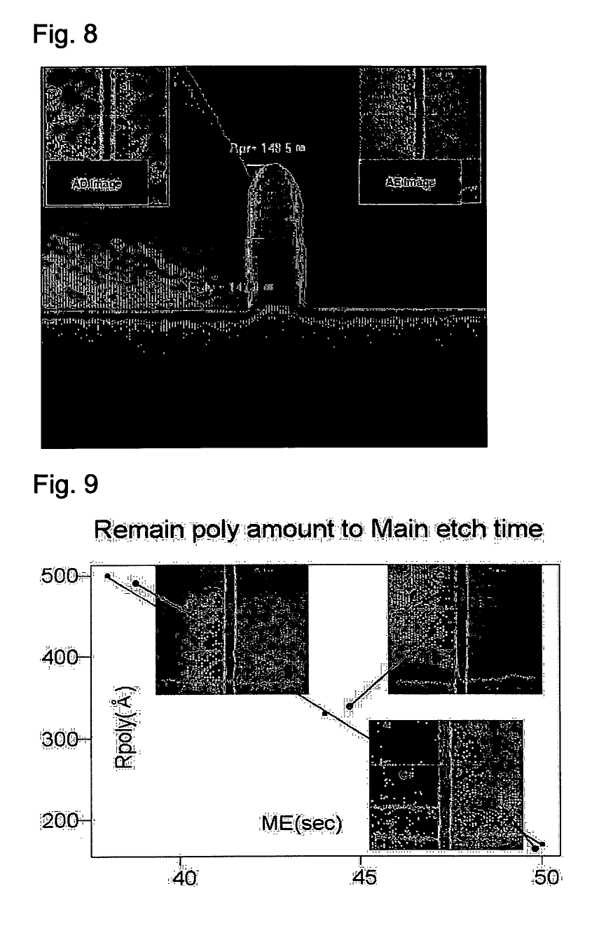

As shown in FIG. 8, a thickness of the PR remaining after an etching process using the described method is measured by using a cross sectional SEM. The thickness is about 1500 Å.

A problem generated in the transistor fabrication is loss of the silicon that is generated because an etching selection ratio between the gate oxide film and the poly silicon is low in the etching process. To solve the problem, the process of etching the poly silicon is performed by two steps; in the first step, the poly silicon remains at about 500 Å and then the remaining poly silicon is removed with a condition that the etching selection ratio of the poly silicon and the gate oxide film is over 50:1.

As shown in FIG. 9, an active pitting is not generated if the poly silicon is about 300 Å thick. The time of etching the poly silicon sets is 35 seconds based on this experiment.

PCM Result

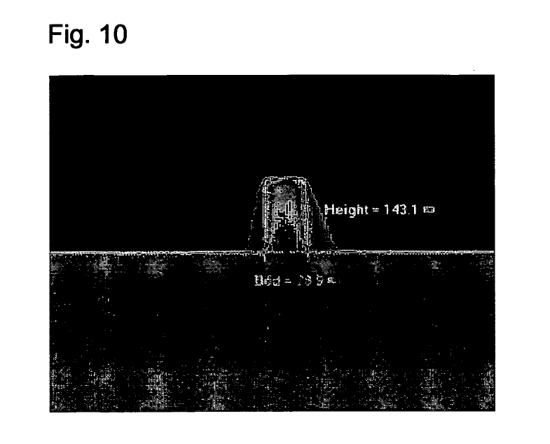

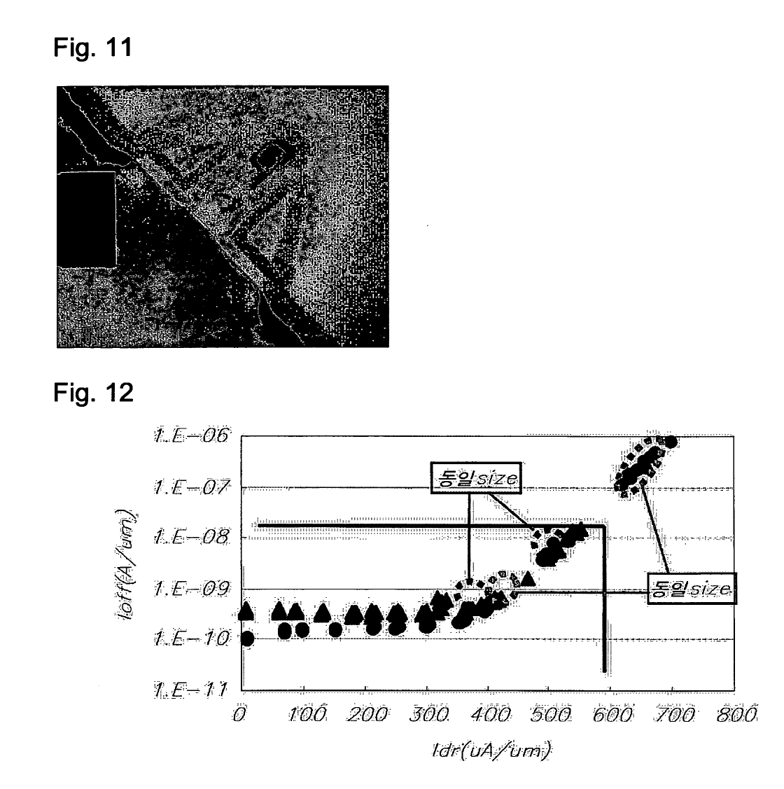

The etching process is optimized based on the results of the experiments to form the transistor so that if the transistor is observed by a transmission electron microscope(TEM), normal profile of FICD 75 nm is obtained as shown in FIGS. 10 and 11.

As shown in a graph of FIG. 12, in aspect of the linearity of an NMOS transistor, Ioff variation according to the Idr variation shows uniform linearity without generating intervals when the ArF is used instead of the KrF. Thus it is known that the method of fabricating the semiconductor transistor is very effective.

The estimating results are put together as follow.

1) After using ArF PR and BARC, if the trim technology is used in the etching process, CD variation can be freely controlled within ranges from about 20 nm to 35 nm and ID variation is about 5 nm and less. Therefore, the line CD can be made larger when the PR pattern is formed so as to obtain the DOF margin.

2) FICD is also changed equally according to changing from 0.100 μm to 0.300 μm as the confirmed result of the transistor. It indicates that the transistor of 85 nm and less can manufacture with the conditions.

3) When the LER of the transistor line is examined, LER 3 sigma is 3 nm and less which is improved compared to the current KrF because the remnants that reduces performance of the PR LER in etching process are removed by the trim technology.

4) The over etching target is rationalized in applying the trim technology and the margin of the PR performing as a mask in etching the poly silicon can secure over 1000 Å by using ArF PR with low plasma tolerance. The active pitting margin can be secured by the method of controlling amount of remaining poly silicon in the first step of the two etching steps of the poly silicon.

5) When rationalizing the etching process as described in the method, the characteristic of Idr and Ioff is improved compared to the current KrF in the transistor of 90 nm or less.

The semiconductor transistor of small size is exactly manufactured consistent with the present invention. Also, the CD variation can easily control and the margin of the DOF is secured by using the method of fabricating the transistor. Moreover, the transistor having linearity is fabricated without remnants and has good electronic characteristic of which size is reduced.

It will apparent by those skilled in the art that various changes and modifications may be made without departing from the spirit and scope consistent with the invention as defined in the following claims.

What is claimed is:

1. A method for fabricating a semiconductor transistor comprising:
sequentially depositing a gate oxide film, a poly silicon, an antireflection film, and a photo-resist on a substrate;
exposing and developing the photo-resist to form a photo-resist pattern having a critical dimension (DICD);
etching the antireflection film using the photo-resist as a mask to form an antireflection film pattern;
etching the poly silicon using the photo-resist as a mask to form a first poly silicon pattern and a second poly silicon pattern on a portion of the gate oxide film; and
removing the second poly silicon pattern and the portion of the gate oxide film.

2. The method according to claim 1, wherein the antireflection film is made of an organic film.

3. The method according to claim 1, wherein etching the antireflection film using the photo-resist as the mask further comprises, etching the photo-resist pattern laterally to form a second photo-resist pattern having a critical dimension FICD which is smaller than DICD.

4. The method according to claim 1, wherein forming the photo-resist pattern comprises using ArF as a light source.

5. The method according to claim 1, wherein etching the antireflection film comprises using a low gas ratio of Cl₂/O₂.

6. The method according to claim 1, wherein etching the antireflection film comprises performing the etching at a low pressure and a low bias power.

7. The method according to claim 1, wherein the thickness of the second poly silicon pattern is on the order of a hundreds of Angstrom.

8. The method according to claim 1, wherein the etching selection ratio of the poly silicon and the gate oxide film is about 50:1.

9. The method according to claim 1, wherein the FICD is 90 nm or less.

10. A method for fabricating a transistor, comprising:
sequentially depositing a gate oxide film, a poly silicon, an antireflection film, and a photo-resist on a substrate;
exposing and developing the photo-resist to form a photo-resist pattern having a critical dimension DICD;
etching the antireflection film using the photo-resist as a mask to form an antireflection film pattern and etching the photo-resist pattern laterally to form a second photo-resist pattern having a critical dimension FICD, wherein FICD is less than DICD;
etching the poly silicon using the photo-resist as a mask to form a first poly silicon pattern under the antireflection film pattern and a second poly silicon pattern on a portion of the gate oxide film; and
removing the second poly silicon pattern and the portion of the gate oxide film.

11. The method according to claim 10, wherein etching the antireflection film comprises using a low gas ratio of Cl₂/0₂.

12. The method according to claim 10, wherein thickness of the second poly silicon pattern is on the order of a hundreds of Angstrom.
